(19) United States
(12) Patent Application Publication
(10) Pub. No.: US 2024/0389461 A1
(43) Pub. Date: Nov. 21, 2024

(54) THERMAL REAWAKENING OPERATION METHOD AND SYSTEM FOR ENHANCING POLARIZATION OF HAFNIUM-BASED FERROELECTRIC THIN FILM

(71) Applicant: HUAZHONG UNIVERSITY OF SCIENCE AND TECHNOLOGY, Hubei (CN)

(72) Inventors: Xingsheng Wang, Hubei (CN); Zichong Zhang, Hubei (CN); Xiangshui MIAO, Hubei (CN)

(73) Assignee: HUAZHONG UNIVERSITY OF SCIENCE AND TECHNOLOGY, Hubei (CN)

(21) Appl. No.: 18/661,690

(22) Filed: May 12, 2024

(30) Foreign Application Priority Data
May 17, 2023 (CN) 202310553633.4

(51) Int. Cl. H10N 30/045; H01L 29/51

(52) U.S. Cl. CPC H10N 30/045; H10N 30/704; H01L 29/516

(57) ABSTRACT

The disclosure discloses a thermal reawakening operation method and system for enhancing polarization of a hafnium-based ferroelectric film, belonging to the field of micro-nanoelectronic technology, which includes the following. S1. Heating is performed on the hafnium-based ferroelectric thin film. S2. A pulse voltage having multiple cycles is applied to the hafnium-based ferroelectric thin film. S3.The hafnium-based ferroelectric thin film is cooled to an initial temperature. In the disclosure, through the thermal reawakening operation, a certain amount of oxygen vacancies are generated, and the non-polarized phase is transformed into the polarized phase, the polarization value of the hafnium-based ferroelectric film can be significantly improved at a low cost and with a simple operation, thereby the performance of the hafnium-based ferroelectric device is significantly improved.

### CROSS-REFERENCE TO RELATED APPLICATION

This application claims the priority benefit of China application serial no. 202310553633.4, filed on May 17, 2023. The entirety of the above-mentioned patent application is hereby incorporated by reference herein and made a part of this specification.

### BACKGROUND

### Technical Field

The disclosure belongs to the field of micro-nanoelectronic technology, and particularly relates to a thermal reawakening operation method and system for enhancing polarization of a hafnium-based ferroelectric thin film.

### Description of Related Art

Since the beginning of the 21st century, with the rapid development of technologies such as big data, the Internet of Things, and cloud computing, the data generated by human society is facing explosive growth. Information technology continues to develop toward faster speeds, higher density, and lower power consumption. As Moore's Law approaches the limit, a series of reliability issues such as quantum effects and random fluctuations have gradually become prominent, and the planar CMOS process seems to be unable to continue Moore's Law. The ever-increasing integration scale poses new challenges to memory, which in turn places new requirements on materials, devices, circuits, and integration processes. Among the challenges, hafnium-based ferroelectric storage technology has been widely recognized in the industry because of the mature material system, simple preparation process, good compatibility with CMOS, meeting the requirements of size miniaturization, high device reliability, and advantages in power consumption and reliability.

For hafnium-based ferroelectric materials, the amount of the polarization value is one of the most critical performance indicators of ferroelectricity. When hafnium-based ferroelectric materials are integrated into devices, polarization plays a key role in the devices. A good polarization window may provide a sufficient margin for the design of peripheral circuits of the storage array, which is particularly important in storage-computing integrated applications. However, improving the polarization value of hafnium-based ferroelectric materials usually involves improving the process, which gradually deviates from the CMOS compatible route. The rising process costs often only bring about a slight performance improvement. Since the ferroelectric mechanism of hafnium-doped thin films has not yet been clarified, it is increasingly difficult to make a major breakthrough in the process. Therefore, a non-process, low-cost, and easy-to-operate method is urgently needed to significantly improve the polarization value of hafnium-based ferroelectric films.

### SUMMARY

In view of the above defects or improvement needs of the related art, the disclosure provides a thermal reawakening operation method for enhancing polarization of a hafnium-based ferroelectric thin film, the purpose of the disclosure is to significantly improve the polarization value of the hafnium-based ferroelectric thin films at a lower cost and with a simple operation.

In order to achieve the above purpose, in the first aspect, the disclosure provides the thermal reawakening operation method for enhancing the polarization of the hafnium-based ferroelectric thin film, which includes steps as follows.
S1. Heating is performed on the hafnium-based ferroelectric thin film.
S2. A pulse voltage having multiple cycles is applied to the hafnium-based ferroelectric thin film.
S3. The hafnium-based ferroelectric thin film is cooled to an initial temperature.

Further preferably, step S1 includes the following. Heating is performed on the hafnium-based ferroelectric thin film, so that a temperature difference between the film and an initial state is 25 to 225° C.

Further preferably, a quantity of the cycles of the pulse voltage is 1 to 10000.

Further preferably, an amplitude of the pulse voltage is 1 to 5V, and a frequency is 0.1 to 10 KHz.

Further preferably, the pulse voltage is a triangular wave pulse, a square wave pulse, or a trapezoidal wave pulse.

Further preferably, a material of the hafnium-based ferroelectric thin film includes a compound comprising Hf element and O element and one or more elements of Zr, Si, Y, La, As, Al, Gd, Sr, P, B, Zn, V, Mo, Ga, and Ge.

In the second aspect, the disclosure provides a thermal reawakening operation system for enhancing polarization of a hafnium-based ferroelectric thin film, which includes the following.

A heating module is configured to perform heating on the hafnium-based ferroelectric thin film.

A pulse operation module is configured to apply a pulse voltage having a plurality of cycles to the hafnium-based ferroelectric thin film.

A cooling module is configured to perform cooling on the hafnium-based ferroelectric

thin film to an initial temperature.

In general, the above technical solutions conceived by the disclosure can achieve beneficial effects as follows.
1. The disclosure provides the thermal reawakening operation method for enhancing the polarization of the hafnium-based ferroelectric thin film. Through the thermal reawakening operation, a certain amount of oxygen vacancies are generated, and the non-polarized phase is transformed into the polarized phase, the polarization value of the hafnium-based ferroelectric film can be significantly improved at a low cost and with a simple operation, thereby the performance of the hafnium-based ferroelectric device is significantly improved.
2. The thermal reawakening operation method for enhancing the polarization of the hafnium-based ferroelectric film provided by the disclosure is highly flexible and can perform multiple polarization enhancements according to different temperatures increased, thereby the flexibility of the use of the hafnium-based ferroelectric film is greatly improved, and the demand for hafnium-based films having high polarization values in integrated arrays is met.

### BRIEF DESCRIPTION OF THE DRAWINGS

FIG. 1 is a flow chart of a thermal reawakening operation method for enhancing polarization of a hafnium-based ferroelectric thin film provided by the disclosure.

FIG. 2 shows a schematic diagram of polarization value results of hafnium-based ferroelectric films after cooling when the increased temperatures of the hafnium-based ferroelectric films are 25° C., 50° C., 75° C., 100° C., 125° C., 150° C., 175° C., 200° C., and 225° C., respectively, provided in Example 1 of the disclosure.

FIG. 3 is a waveform flow chart of the thermal reawakening operation method for enhancing the polarization of the hafnium-based ferroelectric thin film provided in Example 1 of the disclosure.

### DESCRIPTION OF THE EMBODIMENTS

In order to make the purpose, technical solutions, and advantages of the disclosure more comprehensible, the disclosure is further described in detail below together with the accompanying drawings and embodiments. It should be understood that the specific embodiments described herein are only used to explain the disclosure, and the embodiments are not used to limit the disclosure. In addition, the technical features involved in the various embodiments of the disclosure described below may be combined with each other as long as the features do not conflict with each other.

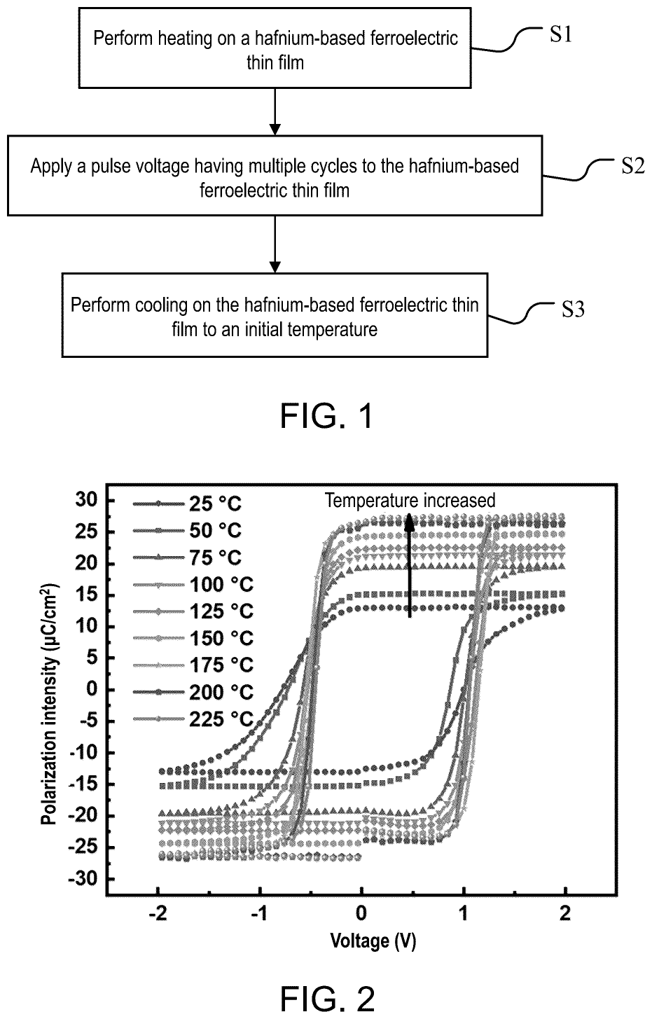

In order to achieve the above purpose, in the first aspect, the disclosure provides a thermal reawakening operation method for enhancing polarization of a hafnium-based ferroelectric thin film, as shown in FIG. 1, which includes steps as follows.
S1. Heating is performed on the hafnium-based ferroelectric thin film.

In an optional implementation manner, heating is performed on the hafnium-based ferroelectric thin film, so that a temperature difference between the film and an initial state is 25 to 225° C.

S2. A pulse voltage having multiple cycles is applied to the hafnium-based ferroelectric thin film.

Specifically, the pulse voltage may be a triangular wave pulse, a square wave pulse, or a trapezoidal wave pulse. In an optional implementation, step S2 includes: the quantity of cycles of the pulse voltage is 1 to 10000, the amplitude is 1 to 5V, and the frequency is 0.1 to 10 KHz.
S3. The hafnium-based ferroelectric thin film is cooled to an initial temperature.

It should be noted that the material of the hafnium-based ferroelectric thin film includes a compound comprising Hf element and O element and one or more elements of Zr, Si, Y, La, As, Al, Gd, Sr, P, B, Zn, V, Mo, Ga, and Ge.

Specifically, in order to illustrate the performance of the thermal reawakening operation method for enhancing the polarization of the hafnium-based ferroelectric thin film provided by the disclosure, the method is described in detail below together with specific embodiments.

### Example 1

The hafnium-based ferroelectric thin film material in this embodiment is Zr-doped HfO₂. Before performing the thermal reawakening operation, first, the initial polarization intensity value of the hafnium-based ferroelectric thin film is read. Specifically, this embodiment uses PUND to read the initial polarization intensity value of the hafnium-based ferroelectric thin film. When implemented, PUND is a triangle wave pulse with an amplitude of 2V and a frequency of 1 kHz.

Then, the thermal reawakening operation is performed on the hafnium-based ferroelectric film, which includes the following.
1) Heating is performed on the hafnium-based ferroelectric film, so that the temperature is raised 25 to 225° C.
2) A pulse voltage of 2V, 1 kHz, 1000 cycles is used to operate on the hafnium-based film. In this embodiment, the pulse square wave amplitude is 2V.
3) Cooling is performed on the hafnium-based ferroelectric film, so that the temperature is dropped to the initial temperature.

Finally, the polarization intensity value of the hafnium-based ferroelectric film after cooling is read again.

Specifically, when the raised temperature of the hafnium-based ferroelectric film is 25° C., 50° C., 75° C., 100° C., 125° C., 150° C., 175° C., 200° C., and 225° C., respectively, the polarization value results of the hafnium-based ferroelectric film after cooling are shown in FIG. 2. It may be seen from the figure that as the temperature increases during the heating process, the polarization intensity value also increases, which is significantly higher than the polarization value of the hafnium-based ferroelectric film before the thermal reawakening operation.

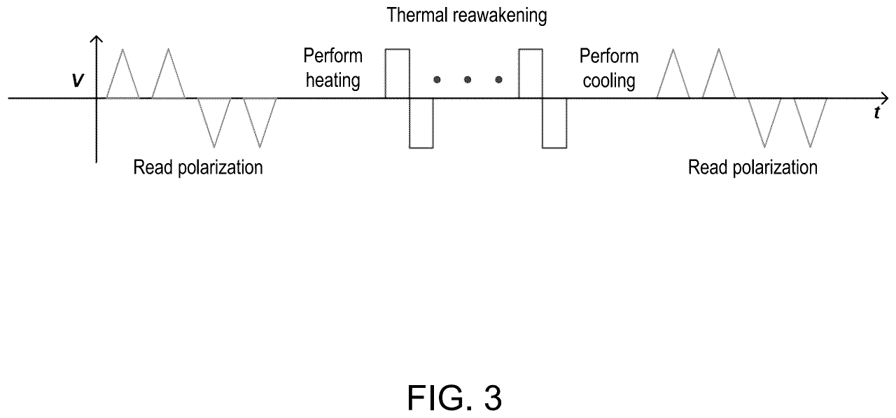

A schematic waveform diagram of the operating voltage of the whole process is shown in FIG. 3.

### Example 2

The operation process of this embodiment is the same as Example 1, except that the hafnium-based ferroelectric thin film material in this embodiment is La-doped HfO₂. Before performing the thermal reawakening operation, first, the initial polarization intensity value of the hafnium-based ferroelectric thin film is read. Then, the method of the thermal reawakening operation performed on the hafnium-based ferroelectric film includes the following.
1) Heating is performed on the hafnium-based ferroelectric film, so that the temperature is raised ΔT. In this embodiment, ΔT is 25° C., 50° C., 75° C., 100° C., 125° C., 150° C., 175° C., 200° C., and 225° C.
2) A pulse voltage of 2V, 1 kHz, 1000 cycles is used to operate on the hafnium-based film.
3) Cooling is performed on the hafnium-based ferroelectric film, so that the temperature is dropped to the initial temperature.

Finally, the polarization intensity value of the hafnium-based ferroelectric film after cooling is read again. Specifically, when the raised temperature of the hafnium-based ferroelectric film is 25° C., 50° C., 75° C., 100° C., 125° C., 150° C., 175° C., 200° C., and 225° C., respectively, the increased polarization result value ΔP of the hafnium-based ferroelectric film after thermal reawakening is shown in Table 1. It may also be seen from the table that as the temperature increases during the heating process, the polarization intensity value of the hafnium-based ferroelectric film also increases, which is much higher than the polarization value of the hafnium-based ferroelectric film before the thermal reawakening operation.

TABLE 1

| ΔT(° C.) | 25 | 50 | 75 | 100 | 125 | 150 | 175 | 200 | 225 |
|---|---|---|---|---|---|---|---|---|---|
| ΔP(μC/ | 5.4 | 10.2 | 16.5 | 20.1 | 24.7 | 28.9 | 30.2 | 32.1 | 34 |
| cm²) | | | | | | | | | |

### Example 3

The operation process of this embodiment is basically the same as Example 1, except that the quantity of cycles of the operation pulse in this embodiment is 1, 10, 100, 1000, and 10000 respectively, and the temperature is increased by 100° C. in step 1). Before performing the thermal reawakening operation, first, the initial polarization intensity value of the hafnium-based ferroelectric thin film is read. Then, the method of the thermal reawakening operation performed on the hafnium-based ferroelectric film includes the following.
1) Heating is performed on the hafnium-based ferroelectric film, so that the temperature is raised 100° C.
2) A pulse voltage with a quantity of cycles of 1, 10, 100, 1000, and 10000 respectively, a frequency of 1 kHz, and an amplitude of 2V is used to operate on the hafnium-based film.
3) Cooling is performed on the hafnium-based ferroelectric film, so that the temperature is dropped to the initial temperature.

Finally, the polarization intensity value of the hafnium-based ferroelectric film after cooling is read again. The increased polarization result value ΔP of the hafnium-based ferroelectric film after thermal reawakening is shown in Table 2. It may be seen from the table that, based on the heating of the base ferroelectric film, as the quantity of cycles of the pulse voltage increases, the polarization intensity value of the hafnium-based ferroelectric film also increases, which is much higher than the polarization value of the hafnium-based ferroelectric film before the thermal reawakening operation.

TABLE 2

| Quantity of cycles | 1 | 10 | 100 | 1000 | 10000 |
|---|---|---|---|---|---|
| ΔP(μC/cm²) | 0.3 | 1.1 | 8.5 | 21.2 | 23.7 |

### Example 4

The operation process of this embodiment is basically the same as Example 1, except that the amplitude of the operation pulse in this embodiment is 1-5V, and the temperature is increased by 100° C. in step 1). Before performing the thermal reawakening operation, first, the initial polarization intensity value of the hafnium-based ferroelectric thin film is read. Then, the method of the thermal reawakening operation performed on the hafnium-based ferroelectric film includes the following.
1) Heating is performed on the hafnium-based ferroelectric film, so that the temperature is raised 100° C.
2) A pulse voltage with a quantity of cycles of 1000, a frequency of 1 kHz, and amplitudes of 1V, 2V, 3V, 4V, and 5V is used to operate on the hafnium-based film.
3) Cooling is performed on the hafnium-based ferroelectric film, so that the temperature is dropped to the initial temperature.

Finally, the polarization intensity value of the hafnium-based ferroelectric film after cooling is read again. The increased polarization result value ΔP of the hafnium-based ferroelectric film after thermal reawakening is shown in Table 3. It may be seen from the table that, based on the heating of the base ferroelectric film, as the pulse voltage amplitude increases, the polarization intensity value of the hafnium-based ferroelectric film also increases, which is much higher than the polarization value of the hafnium-based ferroelectric film before the thermal reawakening operation.

TABLE 3

| Amplitude (V) | 1 | 2 | 3 | 4 | 5 |
|---|---|---|---|---|---|
| ΔP(μC/cm²) | 0.1 | 21.2 | 25.6 | 29.1 | 31.5 |

### Example 5

The operation process of this embodiment is basically the same as Example 1, except that the amplitude of the operation pulse in this embodiment is 0.1-10 kHz, and the temperature is increased by 100° C. in step 1). Before performing the thermal reawakening operation, first, the initial polarization intensity value of the hafnium-based ferroelectric thin film is read. Then, the method of the thermal reawakening operation performed on the hafnium-based ferroelectric film includes the following.
1) Heating is performed on the hafnium-based ferroelectric film, so that the temperature is raised 100° C.
2) A pulse voltage with a quantity of cycles of 1000, a frequency of 0.1 kHz, 1 kHz, and 10 kHz, and an amplitude of 2V is used to operate on the hafnium-based film.
3) Cooling is performed on the hafnium-based ferroelectric film, so that the temperature is dropped to the initial temperature.

Finally, the polarization intensity value of the hafnium-based ferroelectric film after cooling is read again. The increased polarization result value ΔP of the hafnium-based ferroelectric film after thermal reawakening is shown in Table 4. It may be seen from the table that, adopting the method to perform thermal reawakening operation can greatly improve the polarization value of the hafnium-based ferroelectric film.

TABLE 4

| Frequency (kHz) | 0.1 | 1 | 10 |
|---|---|---|---|
| ΔP(μC/cm²) | 28.6 | 21.2 | 8.9 |

In summary, in the disclosure, through the process of the thermal reawakening operation, a certain amount of oxygen vacancies are generated, and the non-polarized phase is transformed into the polarized phase, thereby the polarization value of the hafnium-based ferroelectric film is significantly improved, and the performance of the hafnium-based ferroelectric device is improved. Based on the above, according to the disclosure, the polarization value of the hafnium-based ferroelectric film can be significantly improved at a low cost and with a simple operation.

Furthermore, the thermal reawakening operation method for enhancing the polarization of the hafnium-based ferroelectric film can perform multiple polarization enhancements according to different temperatures increased, thereby the flexibility of the use of the hafnium-based ferroelectric film is greatly improved, and the demand for hafnium-based films having high polarization values in integrated arrays is met.

In the second aspect, the disclosure provides a thermal reawakening operation system for enhancing polarization of a hafnium-based ferroelectric thin film, which includes the following.

A heating module is configured to perform heating on the hafnium-based ferroelectric thin film.

A pulse operation module is configured to apply a pulse voltage having a plurality of cycles to the hafnium-based ferroelectric thin film.

The cooling module is configured to perform cooling on the hafnium-based ferroelectric thin film to an initial temperature.

The related technical solution is the same as the thermal reawakening operation method for enhancing the polarization of the hafnium-based ferroelectric thin film provided in the first aspect, so details will not be repeated here.

It should be understood by persons skilled in the art that the above description is only preferred embodiments of the disclosure and the embodiments are not intended to limit the disclosure. Any modifications, equivalent substitutions, and improvements made within the spirit and principles of the disclosure should be included in the protection scope of the disclosure.

1. A thermal reawakening operation method for enhancing polarization of a hafnium-based ferroelectric thin film, comprising:
S1. performing heating on the hafnium-based ferroelectric thin film, so that a temperature difference between the film and an initial state is 25 to 225° C.;
S2. applying a pulse voltage having a plurality of cycles to the hafnium-based ferroelectric thin film; and
S3. performing cooling on the hafnium-based ferroelectric thin film to an initial temperature.

2. The thermal reawakening operation method according to claim 1, wherein a quantity of the cycles of the pulse voltage is 1 to 10000.

3. The thermal reawakening operation method according to claim 1, wherein an amplitude of the pulse voltage is 1 to 5V, and a frequency is 0.1 to 10 KHz.

4. The thermal reawakening operation method according to claim 1, wherein the pulse voltage is a triangular wave pulse, a square wave pulse, or a trapezoidal wave pulse.

5. The thermal reawakening operation method according to claim 1, wherein a material of the hafnium-based ferroelectric thin film comprises: a compound comprising Hf element and O element and one or more elements of Zr, Si, Y, La, As, Al, Gd, Sr, P, B, Zn, V, Mo, Ga, and Ge.

6. A thermal reawakening operation system for enhancing polarization of a hafnium-based ferroelectric thin film, comprising:
a heating module, configured to perform heating on the hafnium-based ferroelectric thin film, so that a temperature difference between the film and an initial state is 25 to 225° C.;
a pulse operation module, configured to apply a pulse voltage having a plurality of cycles to the hafnium-based ferroelectric thin film; and
a cooling module, configured to perform cooling on the hafnium-based ferroelectric film to an initial temperature.
